(19) United States
(12) Patent Application Publication
(10) Pub. No.: US 2006/0221573 A1
(43) Pub. Date: Oct. 5, 2006

(54) Heat sink for multiple semiconductor modules

(76) Inventor: Ming Li, Fremont, CA (US)

Correspondence Address: MORGAN LEWIS & BOCKIUS LLP/RAMBUS INC., 2 PALO ALTO SQUARE, 3000 EL CAMINO REAL, PALO ALTO, CA, 94306, US

(21) Appl. No.: 11/098,823

(22) Filed: Apr. 4, 2005

(51) Int. Cl. H05K 7/20

(52) U.S. Cl. 361/704

(57) ABSTRACT

A system for dissipating heat away from multiple semiconductor modules includes a thermal conductor having a thermally conductive base and multiple thermally conductive semiconductor module connectors thermally coupled to the base. Each of the semiconductor module connectors is configured to connect to a different semiconductor module of multiple semiconductor modules.

### TECHNICAL FIELD

The embodiments disclosed herein relate to semiconductor devices, and in particular to a system and method for dissipating heat away from multiple semiconductor modules.

### BACKGROUND

As computer systems evolve, so does the demand for increased capacity and operating frequency. However, increases in capacity and operating frequency typically come at a cost, namely an increase in the power consumption of the semiconductor devices. Besides the obvious drawbacks of increased energy costs and shorter battery life, increased power consumption also leads to significantly higher operating temperatures of the semiconductor devices. These higher operating temperatures adversely affect the semiconductor devices' operation. Accordingly, as much heat as possible should be dissipated away from the semiconductor devices during operation.

These problems are exacerbated in computer systems that use a combination of multiple semiconductor devices. Such multiple semiconductor devices are often bundled into a single package, otherwise known as a semiconductor module. However, not only has the demand for increased processing power and memory been increasing rapidly, but there has also been a steady increase in the demand for smaller modules having the same processing capacity and operating frequency. Such smaller modules necessitate an increase in the density of the semiconductor devices within the semiconductor module. However, the close confinement of the semiconductor devices in a semiconductor module package exacerbates heat generation and dissipation problems.

Moreover, many personal computers and servers utilize multiple semiconductor modules. Such semiconductor modules are particularly prevalent in the memory industry, where multiple memory devices are packaged into discrete memory modules. In typical configurations, multiple memory modules are mechanically and electrically connected to a motherboard within the personal computer or server. The memory modules are usually arranged perpendicular to the motherboard and parallel to one another, with very little space between adjacent memory modules. The close spacing of the memory modules also leads to more heat being generated in a confined area, which makes heat dissipation even more difficult.

To aid in the dissipation of the increased heat generation, some memory modules include thermal conductors such as heat spreaders attached to one or both planar sides of the memory module. For example, some Rambus Inline Memory Modules (RIMM) include heat spreaders riveted to both sides of the memory module to assist with heat dissipation. However, such heat spreaders alone may not be sufficient to dissipate the heat generated by the semiconductor modules. Furthermore, the limited space between adjacent memory modules often restricts the use of larger heat spreaders or heat sinks between the adjacent modules. Accordingly, a system and method to more effectively dissipate heat from a semiconductor module would be highly desirable.

Moreover, semiconductor devices within semiconductor modules are typically attached to a printed circuit board (PCB) using solder balls. For high speed memory devices that require a minimum signal delay, wafer level packing (WLP), flip chip on board (FCOB), chip scale packaging (CSP) or even bare die on board is the preferred packaging choice. For all such packaging where the die is dominant in the package, the coefficient of thermal expansion (CTE) of the whole package is about 6 to 8 ppm/C° (parts per million per degree Celsius). If a conventional FR-4 (Flame Retardant 4) PCB with a CTE of 17 to 19 ppm/C° is used, the solder balls may fail from fatigue caused by a CTE mismatch between PCB and memory device during temperature cycling. In other words, the difference between the way two materials expand when heat is applied is critical when semiconductor devices are mounted to printed circuit boards, because the silicon of the semiconductor devices expands at a different rate than the plastic PCB. Accordingly, a system and method for more effectively dissipating heat from a semiconductor module while addressing CTE mismatch would also be highly desirable.

### BRIEF DESCRIPTION OF THE DRAWINGS

For a better understanding of the nature and objects of the invention, reference should be made to the following detailed description taken in conjunction with the accompanying drawings, in which:

FIG. 1 is a partial cross-sectional side view of a system for dissipating heat away from multiple semiconductor modules, according to an embodiment of the invention;

FIG. 2 is another partial cross-sectional side view of another system for dissipating heat away from multiple semiconductor modules, according to another embodiment of the invention;

FIG. 3 is yet another partial cross-sectional side view of yet another system for dissipating heat away from multiple semiconductor modules, according to yet another embodiment of the invention;

FIG. 4 is one other partial cross-sectional side view of one other system for dissipating heat away from multiple semiconductor modules, according to one other embodiment of the invention;

FIG. 5 is a partial cross-sectional side view of an additional system for dissipating heat away from multiple semiconductor modules, according to an additional embodiment of the invention;

FIG. 6 is a further partial cross-sectional side view of a further system for dissipating heat away from multiple semiconductor modules, according to a further embodiment of the invention;

FIG. 7 is a partial cross-sectional side view of a system for dissipating heat away from multiple semiconductor modules, according to an embodiment of the invention; and

FIG. 8 is a block diagram of a system that utilizes the system for dissipating heat away from multiple semiconductor modules, according to an embodiment of the invention.

Like reference numerals refer to the same or similar components throughout the several views of the drawings.

### DETAILED DESCRIPTION OF THE EMBODIMENTS

The following description details various systems for dissipating heat from multiple semiconductor modules. In some embodiments, the system includes a thermal conductor, such as a heat sink, having a thermally conductive base and multiple thermally conductive semiconductor module connectors thermally coupled to the base. Each of the semiconductor module connectors is a mechanical connector that is configured to connect to a different semiconductor module of multiple semiconductor modules. In some embodiments, each of the semiconductor modules includes a substrate having substantially flat opposing first and second sides and first and second opposing edges, at least one semiconductor device electrically and mechanically coupled to the substrate, and electrical connectors disposed on at least one of the first or second sides near the second edge. Each of the semiconductor module connectors may be configured to mechanically and thermally couple to a respective one of the semiconductor modules near the first edge of the semiconductor module.

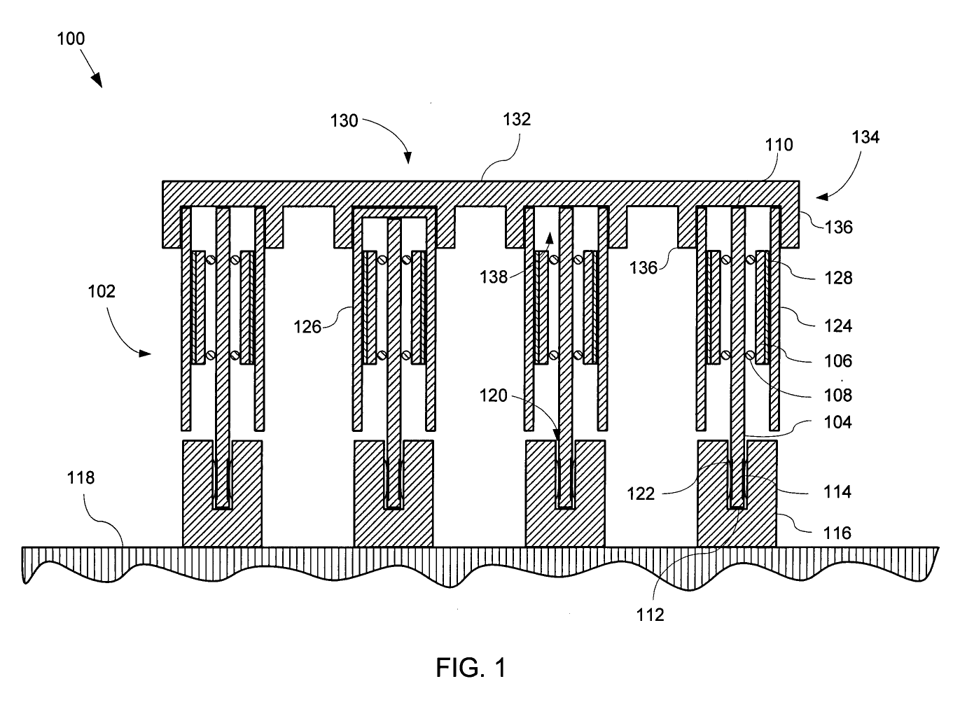

FIG. 1 is a partial cross-sectional side view of a system 100 for dissipating heat away from multiple semiconductor modules 102. In some embodiments, the semiconductor modules 102 are used in personal computers and servers. For example, the semiconductor modules may be memory modules used in a personal computer. Also in some embodiments, the semiconductor modules are aligned substantially parallel to one another in a row, as shown in FIG. 1.

In some embodiments, each semiconductor module includes a substrate 104 having substantially planar opposing sides. In some embodiments, the substrate is a conventional FR-4 printed circuit board. One or more semiconductor devices 106 are attached to one or both of the planar sides by any suitable means, such as through multiple solder balls 108 or the like. Each substrate 104 also includes a first edge 110 and a second edge 112 opposing the first edge. Electrical connectors 114 are located on at least one of the planar sides of each substrate 104 near the substrate's second edge 112. In some embodiments, the combination of the electrical connectors 114 and the substrate 104 form a card-edge connector at the second edge 112 of the substrate 104. Each substrate's electrical connectors 114 are configured to mechanically and electrically mate with a respective female connector 116, which is in turn mechanically and electrically coupled to a motherboard 118 of a computing system, such as a personal computer or a server. Each female connector 116 may include a slot 120 therein for receiving a substrate of a respective semiconductor module 102 therein. Each slot 120 may include one or more resilient electrical contacts 122 that make contact with the electrical connectors 114 of a respective semiconductor module 102.

In the embodiment shown in FIG. 1, each semiconductor module 102 includes at least one thermal conductor such as heat spreader 124, 126 mechanically and thermally coupled thereto. In some embodiments, a separate heat spreader 124 is mechanically and thermally coupled to each semiconductor device 106. In other words, a pair of heat spreaders 124 is used in semiconductor modules with semiconductor devices on both sides of the substrate. In other embodiments, a single U-shaped heat spreader 126 couples to the semiconductor devices on both sides of the semiconductor module 102. The heat spreaders 124, 126 may be mechanically and thermally coupled to the semiconductor devices through a layer of thermal interface material (TIM) 128, thermal paste or the like.

The system 100 also includes a thermal conductor in the form of a heat sink 130 that is coupled to the multiple semiconductor modules to more effectively dissipate heat away from the semiconductor modules 102. The heat sink 130 includes a thermally conductive base 132 and multiple thermally conductive semiconductor module connectors 134 thermally coupled to the base 132. In some embodiments, the base and the connectors are integrally formed. The base and/or connectors may be made from any suitable material that is capable of dissipating heat, such as Al, Cu, Mg, their alloys, or the like.

Each of the semiconductor module connectors 134 is configured to mechanically and thermally couple to a different semiconductor module 102. In some embodiments, each semiconductor module connector 134 includes a set of two substantially parallel ridges 136 defining a slot 138 there between for receiving a different semiconductor module 102. Each set of ridges 136 is configured to form a press or friction fit with an end of a semiconductor module opposite that of or remote from the motherboard 118. Furthermore, in the embodiment shown in FIG. 1, each semiconductor module connector 134 of the heat sink 130 is mechanically and thermally coupled to the heat spreader(s) of each semiconductor module. The semiconductor module connector 134 may be coupled to the heat spreaders 124, 126 either directly or through a layer of thermal interface material (TIM), thermal paste or the like. Furthermore, the heat sink 130 may be clamped to one or more of the semiconductor modules 102. When the heat sink 130 is clamped to the multiple semiconductor modules 102, it locks the multiple semiconductor modules together and provides mechanical stability between the modules and between the modules and the motherboard.

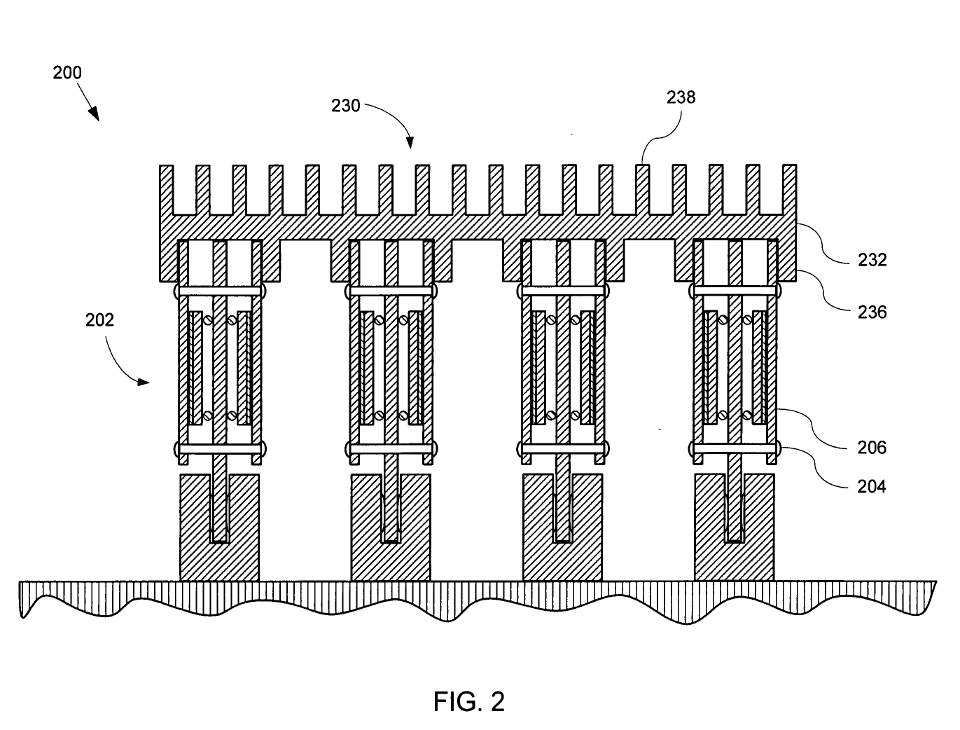

FIG. 2 is another partial cross-sectional side view of another system 200 for dissipating heat away from multiple semiconductor modules. The system 200 includes semiconductor modules 202 that are similar to the semiconductor modules 102 of FIG. 1. However, each semiconductor module 202 uses rivets 204 to mechanically and thermally couple the heat spreaders 206 to the remainder of the semiconductor module. In those embodiments with two heat spreaders per module, the rivets 204 extend through the one heat spreader on one side of the substrate, through the substrate, and through the other heat spreader on the other side of the substrate. In other embodiments with only one heat spreader, the rivets extent through the heat spreader and the substrate. In some embodiments, rivets couple the heat spreader(s) to the remainder of the semiconductor module both above and below the semiconductor devices to ensure even loading of the heat spreaders on the semiconductor devices, as shown.

Also shown in FIG. 2, is another heat sink 230. The heat sink 230 includes a similar base 232 and ridges 236 to those described above in relation to FIG. 1. However, the heat sink 230 includes multiple cooling fins 238 that increase the surface area of the heat sink exposed to the surrounding air, which increases the heat sink's ability to dissipate heat. The base 232 and the cooling fins 238 may be formed integrally with one another.

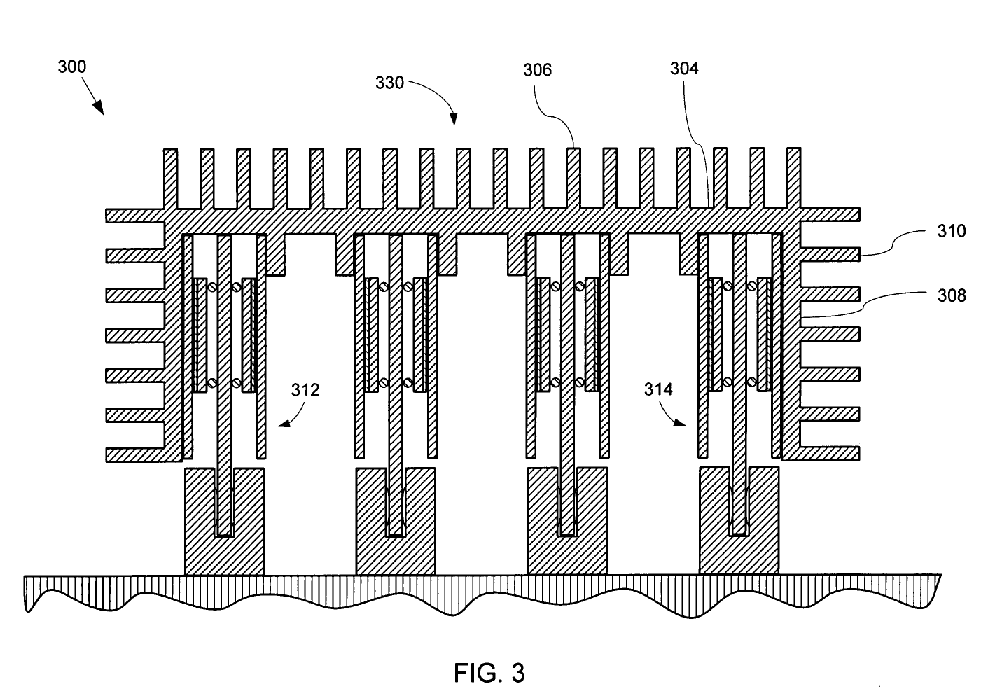

FIG. 3 is yet another partial cross-sectional side view of yet another system 300 for dissipating heat away from multiple semiconductor modules. The system 300 includes a heat sink 330 that is similar to the heat sink 230 of FIG. 2. However, the heat sink 330 includes extensions 308 at each end of the base 304. These extensions 308 are oriented substantially perpendicular to the base 304 and substantially parallel to the semiconductor modules. In some embodiments, depending on the orientation of the semiconductor modules to the motherboard, the extensions 308 may or may not be oriented perpendicular to the base 304 but will generally be parallel to the semiconductor modules. In some embodiments, each extension 308 is mechanically and thermally coupled to first 312 and last 314 semiconductor modules in a row of modules. In other words, the extensions wrap around the first and last modules. The extensions 308 may be mechanically and thermally coupled to the first and last modules through a layer of TIM, thermal paste or the like. Both the base 304 and the extensions may include cooling fins 306, 310, respectively, attached thereto.

In some embodiments, the base 304 and the extensions 308 are formed integrally with one another. In another embodiment, the extensions 308 may be removed and reattached to the base 304 at any position along the base's length. This allows the same heat sink and extensions to be used even if less than the full amount of semiconductor modules are attached to the motherboard.

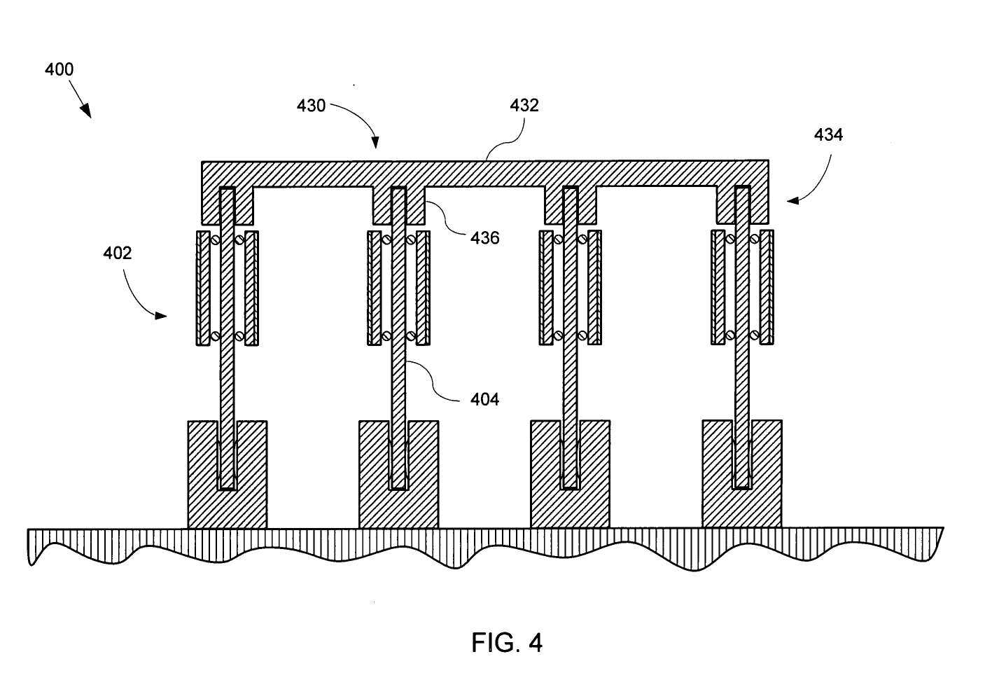

FIG. 4 is one other partial cross-sectional side view of one other system 400 for dissipating heat away from multiple semiconductor modules. The semiconductor modules 402 are similar to the semiconductor modules described above in relation to FIG. 1. However, the semiconductor modules 102 include a substrate 404 that is made from a thermally conductive material, such as Thermalworks Incorporated's STABLCOR PCB. Here, the heat sink 430 is mechanically and thermally coupled to the substrate itself, and not to the heat spreaders, as described above. The heat sink 430 is similar to the heat sinks described, except that it includes multiple thermally conductive semiconductor module connectors 434 that are configured to thermally couple to the thermally enhanced substrate 404 itself. In use, heat generated by the semiconductors is transferred to the thermally enhanced substrate 404. Heat is then transferred to the heat sink 430, which dissipates the heat into the surrounding air. In some embodiments, a suitable substrate is any substrate that has a thermal conductivity of at least 2 W/mK.

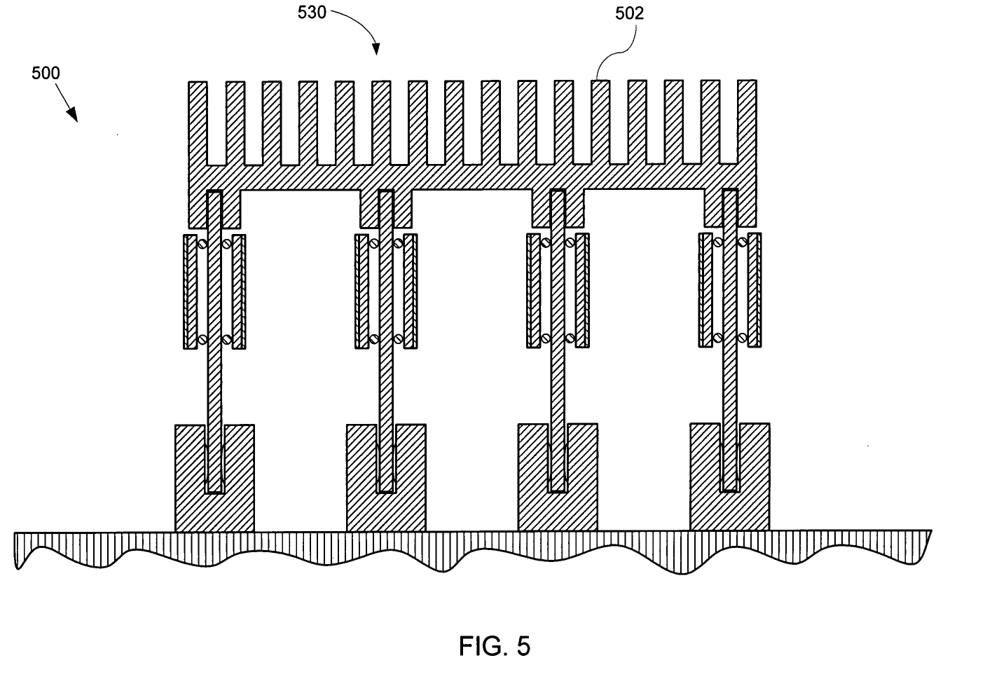

FIG. 5 is a partial cross-sectional side view of an additional system 500 for dissipating heat away from multiple semiconductor modules. This system 500 is similar to system 400 described in relation to FIG. 4. However, system 500 includes a heat sink 530 with multiple cooling fins 502. The cooling fins 502 are similar to the cooling fins 238 of system 200 described above in relation to FIG. 2.

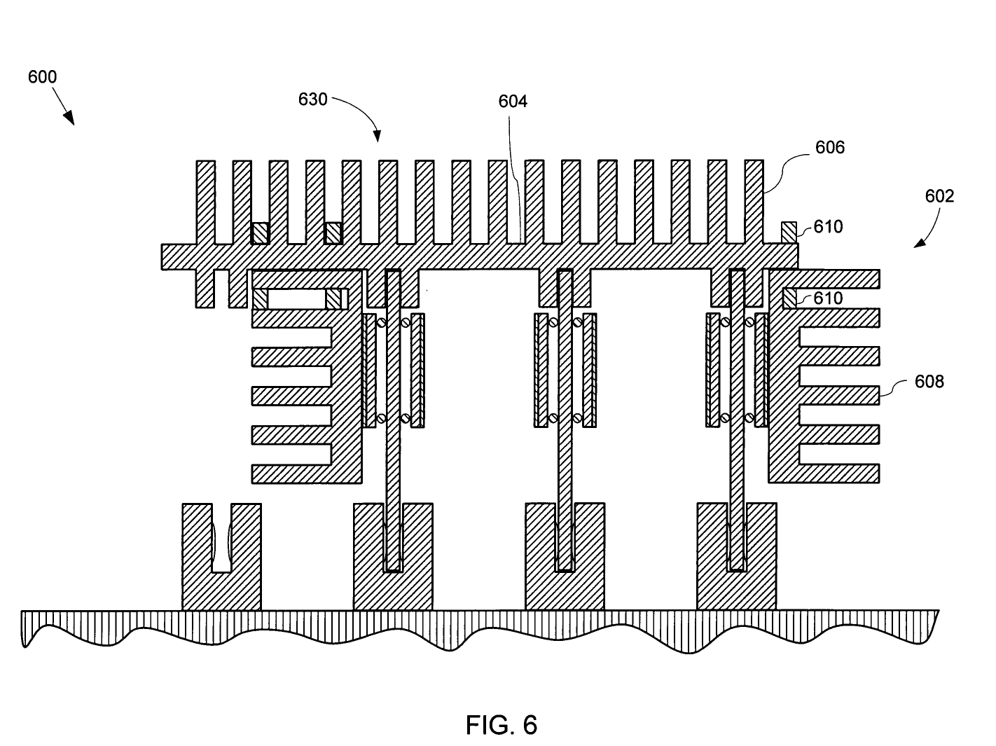

FIG. 6 is a further partial cross-sectional side view of a further system 600 for dissipating heat away from multiple semiconductor modules. The system 600 is similar to the system 500 described above in relation to FIG. 5, however, the system 600 includes extensions 602 extending from each end of a base 604 of a heat spreader 630. These extensions 602 are oriented substantially perpendicular to the base 604 and substantially parallel to the semiconductor modules. In some embodiments, depending on the orientation of the semiconductor modules to the motherboard, these extensions 602 may or may not be oriented perpendicular to the base 604 but will generally be parallel to the semiconductor modules. In some embodiments, each extension 602 is mechanically and thermally coupled to a first and last semiconductor module in a row of modules in a similar manner to that described above in relation to FIG. 3. Both the base 604 and the extensions 602 may include cooling fins 606, 608, respectively, attached thereto.

In some embodiments, as shown, the extensions 602 are separate components that may be removed and reattached to the base 604 at any position along the base's length. The extensions 602 may be coupled to the base 604 using one or more C-shaped clamps 610 that are press-fit onto the base 604 and extensions 602. This allows the same heat sink and extensions to be used even if less than the full amount of semiconductor modules are attached to the motherboard, as shown. In other embodiments, the base 604 and the extensions 602 are formed integrally with one another.

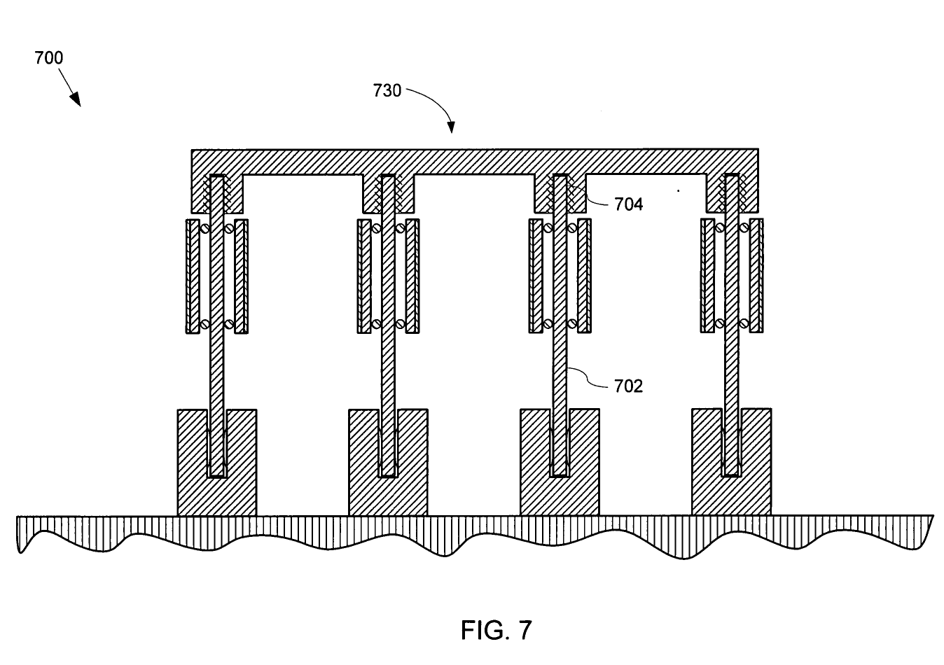

FIG. 7 is a partial cross-sectional side view of a system 700 for dissipating heat away from multiple semiconductor modules. This system 700 is the same as the system 400, however, the first edge of the thermally enhanced substrate 702 is plated with thermally conductive material 704 to aid heat transfer to the heat sink 730. The thermally conductive material 704 may be metal plating, like gold or copper, a thermal interface material (TIM) or the like.

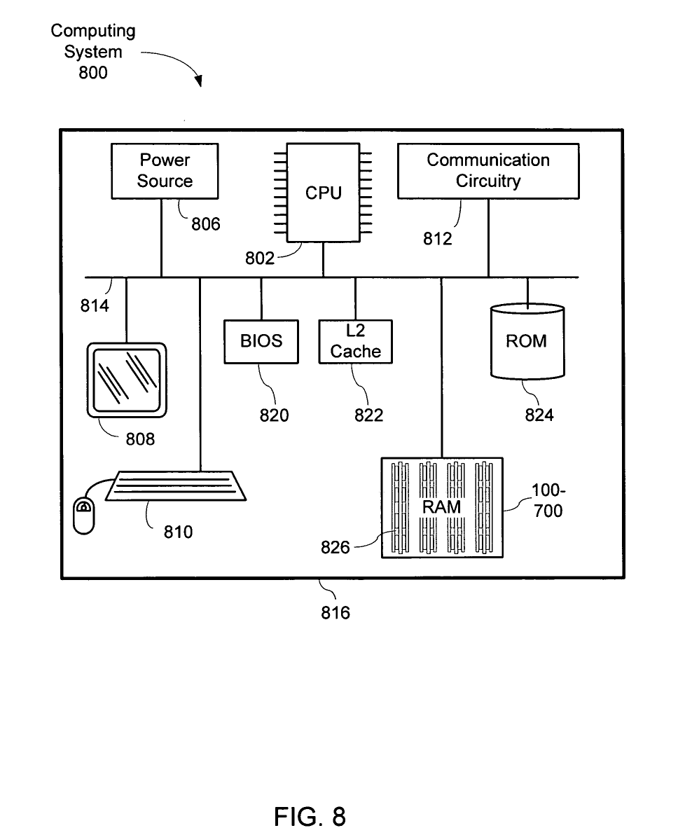

FIG. 8 is a block diagram of a system 800 that utilizes one of the below described systems for dissipating heat away from multiple semiconductor modules. The system 800 includes a plurality of components, such as at least one central processing unit (CPU) 802; a power source 806, such as a power transformer, power supply or batteries; input and/or output devices, such as a keyboard and mouse 808 and a monitor 810; communication circuitry 812; a BIOS 820; a level two (L2) cache 822; Read Only Memory (ROM) 824, such as a hard-drive; Random Access Memory (RAM) 826; and at least one bus 814 that connects the aforementioned components. These components are at least partially housed within a housing 816. Any of the above described systems 100-700 for dissipating heat away from multiple semiconductor modules may be coupled to any of the components that produce heat, such as the CPU 802, BIOS 820, ROM 824 or RAM 826.

Accordingly, a single thermal conductor in the form of a heat sink may be used to efficiently and effectively dissipate heat from multiple semiconductor modules. Additionally, in many of the above-described embodiments, the heat sink also serves as a mechanical interlock or stabilizer, which stabilizes the modules in a substantially vertical orientation with respect to the motherboard.

While the foregoing description and drawings represent the preferred embodiments of the present invention, it will be understood that various additions, modifications and substitutions may be made therein without departing from the spirit and scope of the present invention as defined in the accompanying claims. In particular, it will be clear to those skilled in the art that the present invention may be embodied in other specific forms, structures, arrangements, proportions, and with other elements, materials, and components, without departing from the spirit or essential characteristics thereof. For example, the thermal conductor could be made from any suitable material, such as Al, Cu, Mg and any of their alloys. The thermal conductor may also be made by any suitable manufacturing method, such as stamping, extrusion, die casting or the like. The presently disclosed embodiments are therefore to be considered in all respects as illustrative and not restrictive, the scope of the invention being indicated by the appended claims, and not limited to the foregoing description.

What is claimed is:

1. A system for dissipating heat, comprising:
a thermal conductor comprising:
a thermally conductive base; and
multiple thermally conductive semiconductor module connectors thermally coupled to said base, where each of said semiconductor module connectors is configured to connect to a different semiconductor module of multiple semiconductor modules.

2. The system of claim 1, wherein each of said semiconductor module connectors is configured to couple to an end of a semiconductor module remote from a motherboard.

3. The system of claim 1, wherein each of said semiconductor module connectors is configured to couple to an end of a semiconductor module.

4. The system of claim 1, wherein each of said semiconductor module connectors comprises a set of two parallel ridges defining a slot there between for receiving a respective semiconductor module therein.

5. The system of claim 4, wherein each set of two parallel ridges is configured to form a friction fit with an end of a semiconductor module remote from a motherboard.

6. The system of claim 1, wherein each of said semiconductor modules comprises:
a substrate having substantially flat opposing first and second sides and first and second opposing edges;
at least one semiconductor device electrically and mechanically coupled to said substrate; and
electrical connectors disposed on at least one of said first or second sides near said second edge.

7. The system of claim 6, wherein said electrical connectors are configured to mate with female connectors coupled to a motherboard.

8. The system of claim 6, wherein said heat sink is configured to couple to each of said semiconductor modules near said first edge of each semiconductor module.

9. The system of claim 6, further comprising multiple heat spreaders each coupled to a respective semiconductor module, wherein said heat sink is configured to thermally and mechanically couple to said heat spreaders.

10. The system of claim 6, wherein said substrate is made from a thermally conductive material, and wherein said heat sink is configured to thermally and mechanically couple to said substrate.

11. The system of claim 10, wherein said thermally conductive material has a thermal conductivity of at least 2 W/mK.

12. The system of claim 1 wherein said thermal conductor comprises a heat sink.

13. The system of claim 1, further comprising a layer of thermal interface material (TIM) between the thermal conductor and each semiconductor module.

14. The system of claim 1, wherein said thermal conductor further includes fins extending therefrom to aid heat dissipation.

15. The system of claim 1, wherein said base extends substantially perpendicular to said multiple semiconductor modules.

16. The system of claim 1, further comprising two thermally conductive extensions that extend substantially perpendicular from said base adjacent to and in thermal contact with a first and last of said semiconductor modules arranged in a row.

17. A system for dissipating heat, comprising:
multiple semiconductor modules; and
a thermal conductor comprising:
a thermally conductive base; and
multiple thermally conductive semiconductor module connectors thermally coupled to said base, where each of said semiconductor module connectors is configured to mechanically and thermally couple to a respective semiconductor module of said multiple semiconductor modules.

18. The system of claim 17, wherein each of said semiconductor modules comprises:
a substrate having substantially flat opposing first and second sides and first and second opposing edges;
at least one semiconductor device electrically and mechanically coupled to said substrate; and
electrical connectors disposed on at least one of said first or second sides near said second edge, wherein each of said semiconductor module connectors is configured to couple to a respective one of said semiconductor modules near said first edge.

19. The system of claim 18, wherein said electrical connectors are configured to mate with female connectors coupled to a motherboard of a computer system.

20. The system of claim 18, wherein said substrate is made from a thermally conductive material, and wherein said thermal conductor is configured to thermally and mechanically couple to said substrate.

21. The system of claim 20, wherein said thermally conductive material has a thermal conductivity of at least 2 W/mK.

22. The system of claim 17, wherein each of said semiconductor module connectors comprises a set of two parallel ridges defining a slot there between for forming a friction fit with a respective one of said semiconductor modules.

23. The system of claim 17, further comprising multiple heat spreaders each coupled to a respective semiconductor module of said semiconductor modules, wherein said thermal conductor is configured to thermally and mechanically couple to said heat spreaders.

24. A system for dissipating heat comprising:
multiple semiconductor modules;
a means for conducting heat away from said semiconductor modules; and
multiple means for connecting said semiconductor modules to said means for conducting heat away from said semiconductor modules, where each of said means for connecting is configured to mechanically and thermally couple to a respective semiconductor module of said multiple semiconductor modules.
